(19) United States
(12) Patent Application Publication
(10) Pub. No.: US 2015/0070097 A1
(43) Pub. Date: Mar. 12, 2015

(54) CONFIGURABLE MULTIMODE MULTIBAND INTEGRATED DISTRIBUTED POWER AMPLIFIER

(71) Applicant: DSP Group, Ltd., Herzelia (IL)

(72) Inventors: Abraham Bauer, Hod Hasharon (IL); Eli Schwartz, Tel Aviv (IL); Ilya Sima, Modiin (IL); Lior Blanka, Rosh Haayin (IL); Sergey Anderson, Netanya (IL); Ron Pongratz, Tel Aviv (IL); Alex Mostov, Rishon Le Zion (IL)

(73) Assignee: DSP Group, Ltd., Herzelia (IL)

(21) Appl. No.: 14/540,687

(22) Filed: Nov. 13, 2014

Related U.S. Application Data
(63) Continuation-in-part of application No. 14/033,960, filed on Sep. 23, 2013.
(60) Provisional application No. 61/704,510, filed on Sep. 23, 2012.
(60) Provisional application No. 61/705,150, filed on Sep. 25, 2012.
(60) Provisional application No. 61/720,001, filed on Oct. 30, 2012.
(60) Provisional application No. 61/726,699, filed on Nov. 15, 2012.
(60) Provisional application No. 61/726,717, filed on Nov. 15, 2012.
(60) Provisional application No. 61/727,120, filed on Nov. 16, 2012.
(60) Provisional application No. 61/727,121, filed on Nov. 16, 2012.

(51) Int. Cl. H03F 3/21; H04B 1/04; H04W 88/06; H03F 1/02; H03F 3/193

(52) U.S. Cl. CPC H03F 3/211; H03F 1/0205; H03F 3/193; H04W 88/06; H04B 1/04; H03F 2200/451; H03F 2203/21142; H04B 2001/045
USPC 330/296

(57) ABSTRACT

A novel and useful configurable radio frequency (RF) power amplifier (PA) and related front end module (FEM) circuit that enables manipulation of the operating point of the power amplifier resulting in configurability, multimode and multiband operating capability. The configurable PA also provides high linearity and power efficiency and meets the requirements of modern wireless communication standards such as 802.11 WLAN, 3G and 4G cellular standards, Bluetooth, ZigBee, etc. The configurable power amplifier is made up of one or more configurable sub-amplifiers having each constructed to have several orders of freedom (i.e. biasing points). Each sub-amplifier and its combiner path include active and passive elements. Manipulating one or more biasing points of each sub-amplifier, and therefore of the aggregate power amplifier as well, achieves multimode and multiband operation. Biasing points include, for example, the gain and saturation point, frequency response, linearity level and EVM. An integrated multi-tap transformer having primary and secondary windings arranged in a novel configuration provides efficient power combining and transfer to the antenna of the power generated by the individual sub-amplifiers.

### REFERENCE TO PRIORITY APPLICATION

This application is a continuation-in-part of U.S. application Ser. No. 14/033,960, filed Sep. 23, 2013, entitled “Radio Frequency Front End Module Circuit Incorporating An Efficient High Linearity Power Amplifier,” which claims priority to U.S. Application Ser. No. 61/704,510, filed Sep. 23, 2012, entitled “An Integrated Transformer,” U.S. Application Ser. No. 61/705,150, filed Sep. 25, 2012, entitled “A Method and System for Noise Reduction in Wireless Communication,” U.S. Application Ser. No. 61/720,001, filed Oct. 30, 2012, entitled “System and Method for Radio Frequency Signal Amplification,” U.S. Application Ser. No. 61/726,699, filed Nov. 15, 2012, entitled “DC DC Converter with Fast Output Voltage Transitions,” U.S. Application Ser. No. 61/726,717, filed Nov. 15, 2012, entitled “High-Efficiency Envelop Tracking Method and System Utilizing DC-DC Converter With Fast Output Voltage Transitions,” U.S. Application Ser. No. 61/727,120, filed Nov. 16, 2012, entitled “A Method and Device for Self Aligned PA and LNA VSWR Out/In Improvement, Dynamically Adjust to Antenna,” U.S. Application Ser. No. 61/727,121, filed Nov. 16, 2012, entitled “A Method and Device for Self Aligned Linearity Driven LNA Improvement,” all of which are incorporated herein by reference in their entirety.

### FIELD OF THE INVENTION

The present invention relates to the field of radio frequency (RF) circuits, and more particularly relates to a configurable multimode multiband integrated distributed power amplifier.

### BACKGROUND OF THE INVENTION

Currently, wireless communications systems find application in many contexts involving the transfer of information transfer from one point to another, and there exists a wide range of modalities suited to meet the particular needs of each. These systems include cellular telephones and two-way radios for distant voice communications, as well as shorter-range data networks for computer systems, among many others. Generally, wireless communications involve a radio frequency (RF) carrier signal that is modulated to represent data and the modulation, transmission, receipt and demodulation of the signal conforming to a set of standards. For wireless data networks, example standards include Wireless LAN (IEEE 802.11), Bluetooth (IEEE 802.15.1), and ZigBee (IEEE 802.15.4), which are generally time domain duplex systems where a bidirectional link is emulated on a time divided communications channel.

A fundamental component of a wireless communications system is the transceiver which includes the transmitter and receiver circuitry. The transceiver, with its digital baseband subsystem, encodes the digital data to a baseband signal and modulates the baseband signal with an RF carrier signal. The modulation utilized for WLAN includes orthogonal frequency division multiplexing (OFDM), quadrature phase shift keying (QPSK) and quadrature amplitude modulation (16 QAM, 64 QAM); for WLAN includes GFSK and 4/8-DQPSK; and for Zigbee includes BPSK and OQPSK (or MSK).

Upon receipt of the signal from the antenna, the transceiver downconverts the RF signal, demodulates the baseband signal and decodes the digital data represented by the baseband signal. The antenna connected to the transceiver converts the electrical signal to electromagnetic waves, and vice versa. Depending upon the particular configuration, the transceiver may include a dedicated transmit (TX) line and a dedicated receive (RX) line or the transceiver may have a combined transmit/receive line. In the case of separate TX and RX lines, the transmit line and the receive line are typically tied to a single antenna, particularly for low-cost and/or small-size applications.

The circuitry between the transceiver and the antenna is commonly referred to as the front end module (FEM). The FEM includes an RF power amplifier (PA) which generates output transmit signals by amplifying weaker input signals in wireless devices, such as cellular telephone handsets. Many of these communication devices are configured to operate in different frequency bands for different communication systems. For example, third generation (3G) cellular communication systems, 4G cellular (LTE) systems, 802.11 WLAN systems, etc.

Currently the need for ever increasing data throughput is on the one hand requiring the use of additional bands while on the other hand frequency utilization is becoming tighter in terms of modulation and bits/Hertz efficiency. In one prior art approach in the cellular domain, multi-die power amplifiers are used on a single substrate. Each die serves a specific band and specific linearity requirement. This approach reduces the real estate requirements while addressing frequency band and linearity factors for each band platform. This approach, however, forces multiple switches to select and route the RF signal path from the modulator to the antenna which leads to die overhead and significant losses in the transmit path resulting in reduced TX efficiency.

It is thus desirable to have a distributed power amplifier that avoids the disadvantages of prior art solutions. Preferably, the power amplifier is configurable across difference frequency bands and linearity operating points while reducing the chip real estate required and which is capable of meeting the performance requirements of modern wireless standards such as 802.11, 3G and 4G cellular systems while reducing manufacturing complexities, size and cost.

### SUMMARY OF THE INVENTION

The present invention is a radio frequency (RF) front end module (FEM) circuit incorporating a configurable power amplifier that provides high linearity and power efficiency and meets the requirements of modern wireless communication standards such as 802.11 WLAN, 3G and 4G cellular standards, Bluetooth, ZigBee, etc. The configurable power amplifier is made up of one or more configurable sub-amplifiers having each constructed to have several orders of freedom (i.e. biasing points). Each sub-amplifier and its combiner path include active and passive elements. By manipulating one or more biasing points, for example the gain and saturation point, frequency response, linearity level and EVM of each sub-amplifier as well as the aggregate power amplifier can be determined and set to a desired level. An integrated multi-tap transformer having primary and secondary windings arranged in a novel configuration provide efficient power combining and transfer to the antenna of the power generated by the individual sub-amplifiers.

A significant advantage of the present invention is that the power amplifier can be used to transmit in accordance with a first wireless standard in a first frequency band (e.g., 3G, etc.) and by changing one or more bias settings on one or more sub-amplifiers, the same power amplifier can be configured to transmit in accordance with a second wireless standard in a second frequency band (e.g., LTE, etc.). Thus, the configurable power amplifier eliminates the requirements for multiple dedicated power amplifiers without sacrificing performance and reducing size, die area, board area, cost and interface and glue circuits.

There is thus provided in accordance with the invention, a configurable radio frequency (RF) power amplifier comprising an input node for receiving an RF input signal, an output node for driving a load, a plurality of individually configurable sub-amplifiers configured in parallel and operatively coupled to the input node, each sub-amplifier operative to amplify its respective RF input signal to generate a sub-amplifier output signal therefrom, a control circuit operative to set the operating parameters of each individual sub-amplifier in accordance with a desired operating point, wherein the operating parameters of each sub-amplifier are independently and individually controlled, thereby providing the ability to configure the frequency response and linearity of the configurable power amplifier and wherein the outputs of each sub-amplifier are combined to generate the output node.

There is also provided in accordance with the invention, a configurable radio frequency

(RF) power amplifier comprising an input node for receiving an RF input signal, an output node for driving a load, a driver/splitter circuit operatively coupled to the input node and adapted to split the input RF signal into a plurality of RF signals, a plurality of individually configurable sub-amplifiers operatively coupled to the driver/splitter circuit, wherein each sub-amplifier is adapted to receive one of the RF signals, each sub-amplifier operative to amplify its respective RF input signal to generate a sub-amplifier output signal therefrom, each sub-amplifier biased independently in accordance with respective one or more configurable control points, wherein the operating parameters of each sub-amplifier are independently and individually controlled via the one or more configurable control points, thereby providing the ability to configure the frequency response and linearity of the power amplifier, a control circuit operative to generate and configure the one or more configurable control points for each individual sub-amplifier in accordance with a desired operating point for the power amplifier and a power combiner operatively coupled to the plurality of sub-amplifiers and adapted to combine the power generated by each sub-amplifier to generate the output node thereby.

There is further provided in accordance with the invention, a configurable radio frequency (RF) power amplifier for use in a front end module (FEM) integrated circuit comprising an input node for receiving an RF input signal, an output node for driving a load, a driver/splitter circuit operatively coupled to the input node and adapted to split the input RF signal into a plurality of RF signals, a plurality of individually configurable sub-amplifiers operatively coupled to the driver/splitter circuit, wherein each sub-amplifier is adapted to receive one of the RF signals, each sub-amplifier operative to amplify its respective RF input signal to generate a sub-amplifier output signal therefrom, each sub-amplifier biased independently in accordance with a bias signal, a bias signal generation circuit operative to generate the bias signals for each individual sub-amplifier in accordance with an external bias setting representing a desired operating point for the power amplifier, wherein the operating parameters of each sub-amplifier are independently and individually controlled via a respective bias signal generated in accordance with the external bias setting, thereby providing the ability to configure the frequency response and linearity of the power amplifier as a whole and a power combiner operatively coupled to the plurality of sub-amplifiers and adapted to combine the power generated by each sub-amplifier to generate the output node thereby. Same comments as above

There is also provided in accordance with the invention, a configurable radio frequency (RF) power amplifier for use in a front end module (FEM) integrated circuit comprising an input node for receiving an RF input signal, an output node for driving a load, a driver/splitter circuit operatively coupled to the input node and adapted to split the input RF signal into a plurality of RF signals, a plurality of individually configurable sub-amplifiers operatively coupled to the driver/splitter circuit, wherein each sub-amplifier is adapted to receive one of the RF signals, each sub-amplifier operative to amplify its respective RF input signal to generate a sub-amplifier output signal therefrom, each sub-amplifier biased independently in accordance with a bias signal, a bias signal generation circuit operative to generate the bias signals for each individual sub-amplifier in accordance with a bias control signal representing a desired operating point for the entire power amplifier, a bias control circuit operative to generate the bias control signal in accordance with a desired operating setting stored in a bias setting table, the operating setting table operative to store a plurality of settings for the bias signal generation circuit, each setting entry in the table representing a different desired operating point for the power amplifier, wherein the operating parameters of each sub-amplifier are independently and individually controlled via a respective bias signal, thereby providing the ability to configure the frequency response and linearity of the power amplifier as a whole and a power combiner operatively coupled to the plurality of sub-amplifiers and adapted to combine the power generated by each sub-amplifier to generate the output node thereby.

There is further provided in accordance with the invention, a multimode, multiband configurable radio frequency (RF) power amplifier comprising an input node for receiving an RF input signal, an output node for driving a load, a plurality of individually configurable sub-amplifiers configured in parallel and operatively coupled to the input node, the operating parameters of each sub-amplifier capable of being independently controlled in accordance with a desired operating point, each sub-amplifier operative to amplify its respective RF input signal to generate a sub-amplifier output signal therefrom, wherein the individually configurable sub-amplifiers enable the power amplifier to transmit in accordance with a first wireless standard in a first frequency band and after a change in one or more operating parameters of one or more sub-amplifiers, transmit in accordance with a second wireless standard in a second frequency band and wherein the outputs of each sub-amplifier are combined to generate the output node.

### BRIEF DESCRIPTION OF THE DRAWINGS

The invention is herein described, by way of example only, with reference to the accompanying drawings, wherein:

FIG. 1 is a block diagram illustrating an example dual-band multi-chip front end module (FEM) incorporating a distributed power amplifier constructed in accordance with the present invention;

FIG. 2 is a block diagram illustrating an example single chip FEM circuit incorporating a distributed power amplifier constructed in accordance with the present invention;

FIG. 3 is a block diagram illustrating a first example TX path portion of the FEM circuit incorporating a distributed power amplifier;

FIG. 4 is a block diagram illustrating a second example TX path portion of the FEM circuit incorporating a distributed power amplifier;

FIG. 5 is a block diagram illustrating a third example TX path portion of the FEM circuit incorporating a distributed power amplifier;

FIG. 6 is a block diagram illustrating a fourth example TX path portion of the FEM circuit incorporating a distributed power amplifier;

FIG. 7 is a schematic diagram illustrating a first example differential PA circuit;

FIG. 8 is a schematic diagram illustrating the first example differential PA circuit with the transformer connection shown in more detail;

FIG. 9 is a schematic diagram illustrating a second example differential PA circuit;

FIG. 10 is a schematic diagram illustrating the second example differential PA circuit with the transformer connection shown in more detail;

FIG. 11 is a schematic diagram illustrating a third example differential PA circuit;

FIG. 12 is a schematic diagram illustrating a first example TX/RX switch;

FIG. 13 is a schematic diagram illustrating a second example TX/RX switch; and

FIG. 14 is a high level block diagram illustrating an example wireless device incorporating a FEM circuit with distributed power amplifier of the present invention.

### DETAILED DESCRIPTION OF THE INVENTION

The present invention is a configurable radio frequency (RF) power amplifier (PA) and related front end module (FEM) circuit that enables manipulation of the operating point of the power amplifier resulting in configurability, multimode and multiband operating capability. The configurable PA also provides high linearity and power efficiency and meets the requirements of modern wireless communication standards such as 802.11 WLAN, 3G and 4G cellular standards, Bluetooth, ZigBee, etc. The configurable power amplifier is made up of one or more configurable sub-amplifiers having each constructed to have several orders of freedom (i.e. biasing points). Each sub-amplifier and its combiner path include active and passive elements. Manipulating one or more biasing points of each sub-amplifier, and therefore of the aggregate power amplifier as well, achieves multimode and multiband operation. Biasing points include, for example, the gain and saturation point, frequency response, linearity level and EVM. An integrated multi-tap transformer having primary and secondary windings arranged in a novel configuration provides efficient power combining and transfer to the antenna of the power generated by the individual sub-amplifiers.

RF circuitry such as the transceiver is typically fabricated as integrated circuits typically using complementary metal-oxide semiconductor (CMOS) technology due to the miniature device size and lower cost. Wireless communication links must be reliable and have high data throughput over wide distances which necessitate higher power levels at the antenna output. For instance, the aforementioned Wireless LAN and Bluetooth typically require average power levels of 20 dBm (i.e. 100 mW) or more.

Higher power output, however, requires higher current and voltage levels in the RF circuitry. Many CMOS devices are currently produced with a 0.18-micron process with advanced systems utilizing 130 nm, 90 nm, 65 nm, and 45 nm processes. The resulting integrated circuits have operating voltages in the range of 1.8 V to lower than 1.2 V because of the reduced break down voltages of the semiconductor devices therein. Average power levels of +20 dBm at 1.8 V have been difficult to achieve particularly for signals having envelope variations which is the case with OFDM, QPSK, QAM, etc. Increasing power requirements typically leads to decreased efficiency because of a greater proportion of power being lost as heat with subsequent decreased battery life. In addition, the impedance is lowered for the same power level with increased current. Considering that most RF circuits are designed to have 50 Ohm impedance the design of matching circuits for decreased impedance is also problematic due to increased power losses.

Conventional transceivers for cellular, WLAN, Bluetooth, ZigBee, etc. typically do not generate sufficient power or have sufficient RX sensitivity necessary for reliable communications in many scenarios. Current integrated circuit transceiver devices have transmit average power levels of below 10 dBm, though there are some devices that have power levels of 10 or 20 dBm, which is still less than the desired 20-25 dBm. Accordingly, additional conditioning of the RF signal is necessary.

The circuitry between the transceiver and the antenna is commonly referred to as the front end module or FEM. The FEM includes a power amplifier for increased transmission power and a low noise amplifier (LNA) for increased reception sensitivity. Various filter circuits such as band pass filters may also be included to provide a clean transmission signal at the antenna and to protect the reception circuitry from external blocking signals reaching the antenna. The FEM also includes an RF switch to rapidly switch between receive and transmit functions and to prevent interference during the transitions between transmission and reception.

The present invention provides a PA circuit and a FEM circuit incorporating the PA that addresses the issues identified above. The PA circuit of the present invention provides high linearity and power efficiency and meets the requirements of modern wireless communication standards such as 802.11 WLAN, 3G and 4G cellular standards, etc. In addition, the configuration of the PA circuit permits the use of common, relatively low cost semiconductor fabrication techniques such as commercially available CMOS processes.

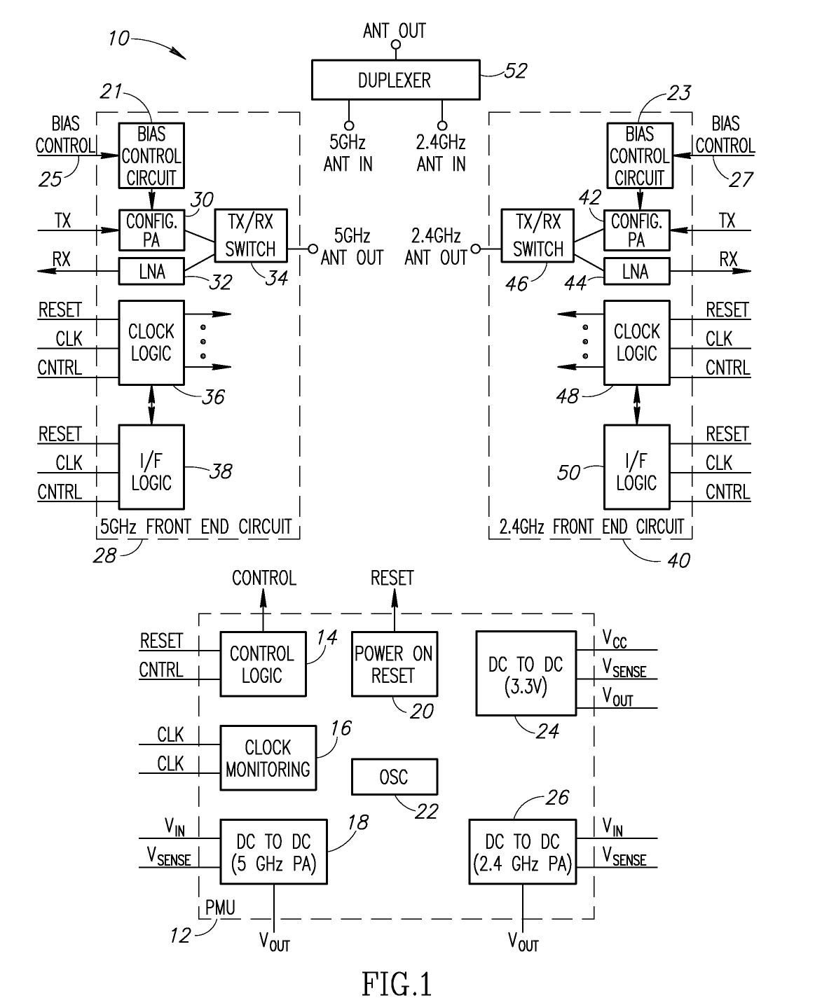

A block diagram illustrating an example dual-band multi-chip front end module (FEM) incorporating a configurable distributed power amplifier constructed in accordance with the present invention is shown in FIG. 1. The dual band FEM module, generally referenced 10, comprises four modules including a duplexer 52, 2.4 GHz FEM circuit module 40, 5 GHz FEM circuit module 28 and power management unit (PMU) module 12. The 2.4 GHz FEM circuit 28 is operative to receive and transmit signals in the 2.4 GHz ISM band while the 5 GHz FEM circuit is operative to receive and transmit signals in the 5 GHz ISM band. Each of the modules may be constructed on individual integrated circuits with printed or wire bond connections between the chips. Alternatively, the FEM module may comprise a single integrated circuit and/or may handle a single frequency band.

The duplexer 52 functions to couple one or more antennas to the 2.4 and 5 GHz antenna ports. The PMU 12, which is optional in the circuit, may comprise part or all the following: a DC-DC converter 24 (e.g., 3.3V), power on reset circuit 20, oscillator circuit 22 for generating clock signals, biasing circuits and RF power ramp-up control, DC-DC converter circuit 26 for the 2.4 GHz power amplifier (PA), DC-DC converter circuit 18 for the 5 GHz PA, clock monitoring circuit 18 and control logic 14.

The 2.4 GHz FEM circuit module 40 comprises a bias control circuit 23 and bias control signal input 27, a TX/RX switch 46, power amplifier circuit 42, low noise amplifier (LNA) circuit 44, control logic 48 and interface (I/F) logic 50. The PA 42 functions to amplify the TX signal output of the baseband circuit for broadcast through the antenna. The LNA 44 functions to amplify the receive signal received from the antenna and output an RX signal for demodulating and decoding by the baseband circuit.

Similarly, the 5 GHz FEM circuit module 28 comprises a bias control circuit 21 and bias control signal input 25, TX/RX switch 34, power amplifier circuit 30, low noise amplifier (LNA) circuit 32, control logic 36 and interface (I/F) logic 38. The PA 30 functions to amplify the TX signal output of the baseband circuit for broadcast through the antenna. The LNA 32 functions to amplify the receive signal received from the antenna and output an RX signal for demodulating and decoding by the baseband circuit.

In one embodiment of the present invention, the performance of the distributed amplifier fabricated on a single die is manipulated (i.e. controlled) through an external control bus. The control not only provides an opportunity to tune the linearity level of the power amplifier but also to dramatically influence the frequency response of the amplifier.

In one embodiment, the performance of the power amplifier is maximized by attempting to optimize the performance around a very specific narrow frequency band. For example, an amplifier can be optimized for operation around a frequency of 1.8 GHz. Such an amplifier, however, will not satisfactorily cover the 1.9 GHz frequency band. In another embodiment, the passive components of the power amplifier can be made configurable to cover multiple frequency bands. This embodiment, however, does not provide sufficient desired performance.

In another embodiment, a configurable wideband linear power amplifier is constructed with an optional saturated amplifier that is active at peak power levels. The amplifier is a distributed amplifier comprising multiple configurable amplifiers (referred to as configurable sub-amplifiers) configured in parallel which utilize a power combiner to aggregate the RF power in phase.

Such an embodiment is constructed to have several orders of freedom (i.e. biasing inputs or control inputs). Each configurable sub-amplifier and its combiner path include active and passive elements. By manipulating one or more biasing points, for example the gain and saturation points of each sub-amplifier, the frequency response, linearity level and EVM of the combined aggregate power amplifier can be determined and set to a desired level. In one embodiment of the amplifier constructed by the inventors, performance of the power amplifier can be manipulated in the range of 3-7 dB which, as an example, is the range required to distinguish between amplifier requirements for 2G and 3G. In addition, since the frequency response is capable of being tuned within 10% of the bandwidth, the adjacent frequency bands of various modes can be covered by the power amplifier of the present invention. As advantage of the resulting power amplifier constructed in this fashion is that it is capable of replacing multiple separate die amplifiers in adjacent frequency bands and eliminate the respective losses from switching elements that are no longer required.

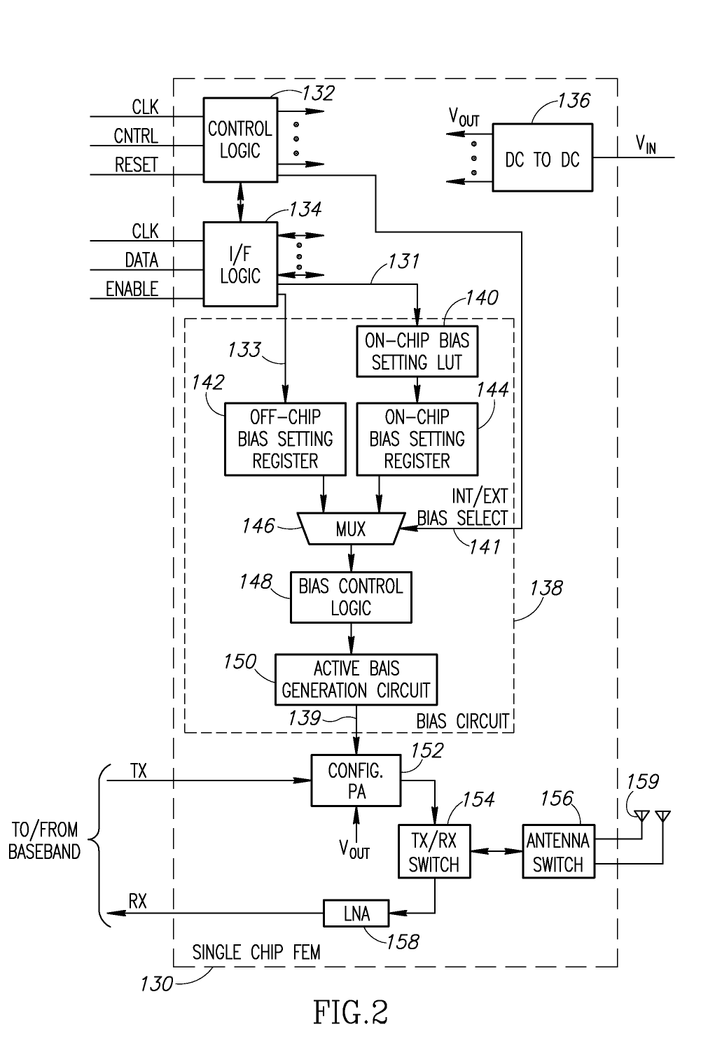

A block diagram illustrating an example single chip FEM circuit incorporating a configurable distributed power amplifier constructed in accordance with the present invention is shown in FIG. 2. The single chip FEM circuit, generally referenced 130, comprises a configurable PA circuit 152 for amplifying a TX signal from the baseband circuit for broadcast through one or more antennas 159, an LNA circuit 158 for amplifying the received signal from one or more of the antennas and output an RX signal for demodulation and decoding by the baseband circuit, a TX/RX switch 154 for coupling either the PA or the LNA to the antenna, optional antenna switch 156 for coupling the TX/RX switch to one or more antennas 159, bias circuit 138, control logic 132, I/F logic 134 and DC-DC converter circuit 136.

Multiple antennas 159 may be used in a system employing spatial diversity for example. In a MIMO system, multiple antennas are employed but each antenna has its own associated FEM circuit where the combining of the multiple receive signals and generating of multiple transmit signals is performed via signal processing in the baseband circuit.

The bias circuit 138 is operative to generate one or more bias signals 139 to the configurable power amplifier 152 from either an internal or external bias select. The bias circuit comprises an on-chip bias setting look up table (LUT) 140 which receives an on-chip bias selection signal 131 for selecting one of a plurality of bias profiles stored in the LUT or other memory. Any number of operating points or configurations for the sub-amplifiers making up the distributed power amplifier can be determined a priori (i.e. predetermined or pre-calculated) and stored on the LUT. To change operating the operating mode of the PA simply requires a difference command to be input to the LUT. Based on its input command, the LUT outputs the corresponding bias control data points necessary to configure the sub-amplifier to the desired gain, frequency band, linearity, EVM, etc.

In one embodiment, the output of the LUT 140 is written to an on-chip bias setting register 144. For off-chip control of the power amplifier, an off-chip bias setting register 142 is used to store the bias control data points that are provided by an off-chip source rather than the on-chip LUT. A multiplexer (MUX 146) selects either the off-chip or on-chip bias control data points in accordance with an internal/external bias select signal 141 generated by the control logic block 132.

The bias control data output of the multiplexer 146 is input to the bias control logic 148 which translates the bias control data points to the necessary bias control signals. These are then input to the active bias generation circuit 150 which is operative to generate the actual individual bias signals used by the sub-amplifiers to manipulate their various orders of freedom and configurability, e.g., frequency, linearity, gain, etc.

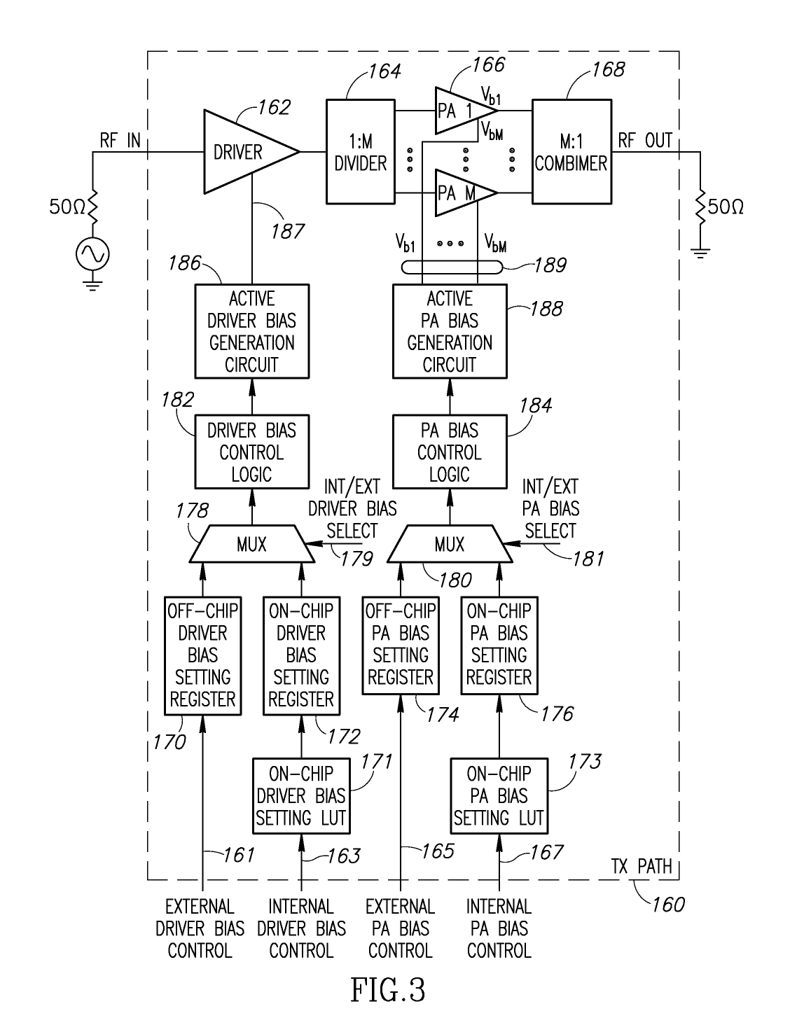

A block diagram illustrating a first example TX path portion of the FEM circuit incorporating a distributed power amplifier is shown in FIG. 3. The first example TX path, generally referenced 160, comprises a driver 162 operative to receive an RF input, a 1:M divider 164 (where M is greater than or equal to one) operative to divide the signal output of the driver 162, a plurality of M configurable sub-amplifiers 166 each having a plurality of control points and an M:1 combiner 168 operative to generate the aggregate amplified RF output signal.

In operation, in the event driver bias is provided from an off-chip source, an external driver bias control signal 161 provided by the external source is written to an off-chip driver bias setting register 170. In the event driver bias is provided by the on-chip source, an internal driver bias control 163 is input to an on-chip driver bias look up table (LUT) 171 which is operative to output the driver bias control data points subsequently written to the on-chip driver bias setting register 172. A multiplexer 178 selects either the off-chip or on-chip driver bias setting in accordance with an internal/external driver bias select signal 179. The output of the multiplexer is input to the driver bias control logic 182 which provides the required bias settings in accordance with the desired driver operating point. These bias settings are input to the active driver bias generation circuit 186 which is operative to generate the individual driver bias signals 187 input to the driver circuit 162.

Similarly, in the event amplifier bias is provided from an off-chip source, an external PA bias control signal 165 provided by the external source is written to an off-chip PA bias setting register 174. In the event amplifier bias is provided by the on-chip source, an internal PA bias control 167 is input to an on-chip PA bias look up table (LUT) 173 which is operative to output the PA bias control data points subsequently written to the on-chip PA bias setting register 176. A multiplexer 180 selects either the off-chip or on-chip driver bias setting in accordance with an internal/external PA bias select signal 181. The output of the multiplexer is input to the PA bias control logic 184 which provides the required bias settings in accordance with the desired PA operating point. These bias settings are input to the active PA bias generation circuit 188 which is operative to generate the individual PA bias signals V_{b1-M} 189 input to the plurality of sub-amplifiers 166.

Typically, the contents of the LUT for both the driver and sub-amplifiers are determined a priori. The bias setting points for multiple operating profiles are calculated and loaded into the LUT. Note that the driver bias selection is optional and may be omitted depending on the particular implementation. The PA bias selection, however, is operative to provide the desired manipulation of the operating point of the power amplifier and is responsible for providing its configurability, multimode and multiband operating capability.

Note that in one embodiment, each sub-amplifier comprises the appropriate control points, e.g., tuning capacitors, etc., to change to working point of the sub-amplifier. For example, by manipulating the bias signal input to the sub-amplifier, tuning and de-tuning of frequency response and linearity can be achieved. Any number of sub-amplifiers can be implemented with each being independently controlled through one or more bias control signals. Thus, utilizing active configurable independent sub-amplifiers in combination with passive elements in the splitter and combiner circuits, a desired aggregate response from the configurable power amplifier can be achieved to provide multimode, multiband operation.

In one embodiment, the configurable power amplifier and FEM circuit is constructed using standard complementary metal oxide semiconductor (CMOS) integrated circuit technology. Alternatively, the FEM circuit may be fabricated using any suitable semiconductor technology such as Gallium Arsenide (GaAs), Silicon Germanium (SiGe), Indium Gallium Phosphide (InGaP), Gallium Nitride (GaN), etc. Using CMOS technology, however, is desirable due to lower cost and complexity and the ability to integrate digital logic with analog circuitry.

In one embodiment, the power amplifier circuit is constructed from a plurality of sub-power amplifiers or sub-amplifiers. The input signal is split and fed to each of the sub-amplifiers, which provides a portion of the total desired gain of the power amplifier. The outputs of each of the sub-amplifiers are combined to generate the RF output signal. In one embodiment, the combiner element comprises a multi-tap transformer. Note that in the example configurable power amplifier embodiments presented herein, the load may comprise a filter, switch, antenna tuning element or other component depending on the particular implementation and application of the invention.

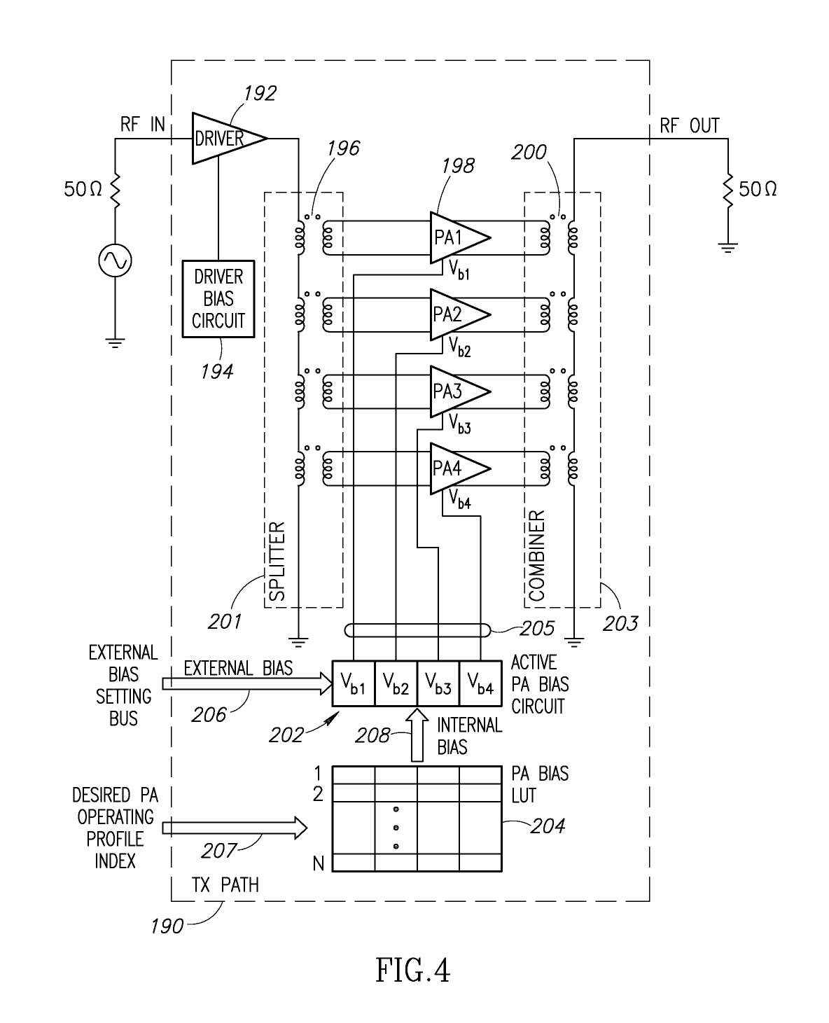

A block diagram illustrating a second example TX path portion of the FEM circuit incorporating a configurable distributed power amplifier is shown in FIG. 4. The TX path, generally referenced 190, comprises a driver circuit/buffer 192, power splitter 201, one or more differential configurable sub-amplifiers 198, driver bias circuit 194, active PA bias circuit 202, PA bias LUT 204 and power combiner 203. In operation, the RF input signal is input to a driver circuit whose output is input to the splitter. The splitter functions to provide an input signal to each of the configurable sub-amplifiers 198. In one embodiment, the splitter 201 comprises a multi-tap transformer 196 having a primary winding and multiple secondary windings, one secondary for each sub-amplifier. Each sub-amplifier may be adapted to handle either a differential (shown) or single ended input signal. The differential output of each sub-amplifier 198 is coupled to a corresponding primary winding of a multi-tap combiner transformer 200. The output signal is generated in the secondary winding and provides the RF output of the TX path circuit. Note that in the case of four sub-amplifiers, the impedance of each winding tap is adapted to be approximately 12.5 Ohm to yield a desired RF output impedance of approximately 50 Ohm. It is appreciated that the power amplifier may comprise any number of configurable sub-amplifiers depending on the particular implementation.

In operation, the RF output signal is generated from the combination of the individual outputs of the sub-amplifiers. Each sub-amplifier contributes a portion of the total power required from the power amplifier circuit. The power generated by each sub-amplifier is combined via the combiner multi-tap transformer to generate the RF output signal having a combined total RF power.

The bias settings for the configurable sub-amplifiers can be provided externally or internally. For external bias control, a bias setting is provided via an external bias setting bus 206 which inputs the particular bias control data points required for the desired operating profile of the power amplifier. The bias control data points are input to the active PA bias circuit 202 which generates the plurality of individual bias signals 205 which are input to the individual sub-amplifiers. Note that in this example of four sub-amplifiers, four sets of one or more bias signals (grouped as V_{b1-4}) are input to the sub-amplifiers. It is appreciated that the power amplifier may comprise any number of configurable sub-amplifiers with each sub-amplifier having any number of bias control points.

For internal bias control, the desired PA operating profile index 207 is input to a PA bias LUT 204. In accordance with the index, the LUT outputs a corresponding internal bias 208 consisting of one or more bias control data points. These bias control data points are input to the active PA bias circuit 202 and used to generate the plurality of individual bias signals 205 which are input to the individual sub-amplifiers.

Note that differential amplifiers (or balanced amplifiers) are preferable in that they enable a doubling of the voltage swing that can be applied to a balanced load. This quadruples the output power without incurring any additional stress on the transistors. Thus, an efficient power amplifier is realized utilizing differential sub-amplifier stages.

Utilizing the mechanism of the present invention, the power amplifier can be used to transmit in accordance with a first wireless standard in a first frequency band (e.g., 3G, etc.) and by changing one or more bias settings on one or more sub-amplifiers, the same power amplifier can be configured to transmit in accordance with a second wireless standard in a second frequency band (e.g., LTE, etc.). Thus, the configurable power amplifier eliminates the requirements for multiple dedicated power amplifiers without sacrificing performance and reducing size, die area, board area, cost and interface and glue circuits.

In one embodiment, both the splitter and combiner transformers are fabricated in CMOS and integrated on the same die with other analog and digital circuitry. In alternative embodiments, the transformers are fabricated using other technologies such as GaAs, InGaP, GaN, etc. The transformers comprise air cores and may take on any suitable shape and configuration. Several examples of integrated multi-tap transformers are described in more detail infra. Note that in one embodiment, the transformer is constructed to be relatively broadband so as to be able to both 2.4 and 5.8 GHz WLAN signals. Alternatively, a diplexer, constructed from two transformers and two band pass filters, one transformer and band pass filter for each frequency band. Note that the FEM circuit of the present invention is applicable to not only WLAN signal but any modulation scheme that exhibits high peak to average ratio, e.g., 3G, 4G LTE, etc.

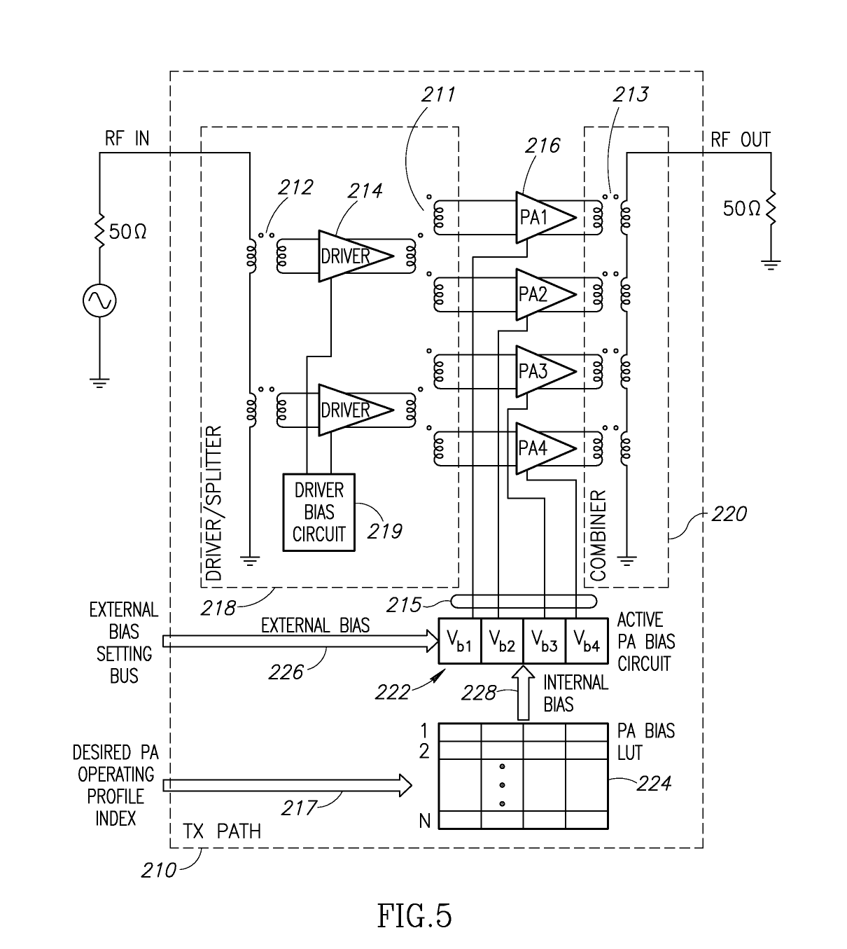

A schematic diagram illustrating a second example differential PA circuit is shown in FIG. 5. The TX path, generally referenced 210, comprises a driver/splitter circuit 218, one or more configurable differential sub-amplifiers 216, active PA bias circuit 222, PA bias LUT 224 and power combiner 220. The driver/splitter 218 comprises multi-tap transformer 212 having a primary winding and two secondary windings, one secondary winding for each differential driver 214 and driver bias circuit 219. Multi-tap transformer 211 comprises a pair of one-to-two transformers each having a primary winding associated with driver 214 and secondary windings for two sub-amplifiers 216. The combiner 220 comprises a multi-tap transformer 213 having a primary winding associated with each sub-amplifier 216 and a secondary winding for generating the RF output signal.

In operation, the RF input signal is input to a driver circuit 218 that splits the RF input signal into two signals. Each of the signals is input to a driver 214 whose output is further split into two signals. The splitter functions to provide an input signal to each of the sub-amplifiers 216. In one embodiment, the splitter comprises transformers 212, 211 and driver circuit 214. Each configurable sub-amplifier may be adapted to handle either a differential (shown) or single ended input signal. The differential output of each sub-amplifier is coupled to a corresponding primary winding of a multi-tap combiner transformer 213. The output signal is generated in the secondary winding and provides the RF output of the TX path circuit. Note that for an example TX path with four sub-amplifiers, the impedance of each winding tap is adapted to be approximately 12.5 Ohm to yield a desired RF output impedance of approximately 50 Ohm.

In operation, the RF output signal is generated from the combination of the individual outputs of the sub-amplifiers. Each sub-amplifier contributes a portion of the total power required from the power amplifier circuit. The power generated by each sub-amplifier is combined via the combiner multi-tap transformer to generate the RF output signal having a combined total RF power.

The bias settings for the configurable sub-amplifiers can be provided externally or internally. For external bias control, a bias setting is provided via an external bias setting bus 226 which inputs the particular bias control data points required for the desired operating profile of the power amplifier. The bias control data points are input to the active PA bias circuit 222 which generates the plurality of individual bias signals 215 which are input to the individual sub-amplifiers. Note that in this example of four sub-amplifiers, four sets of one or more bias signals (grouped as V_{b1-4}) are input to the sub-amplifiers. It is appreciated that the power amplifier may comprise any number of configurable sub-amplifiers with each sub-amplifier having any number of bias control points.

For internal bias control, the desired PA operating profile index 217 is input to a PA bias LUT 224. In accordance with the index, the LUT outputs a corresponding internal bias 228 consisting of one or more bias control data points. These bias control data points are input to the active PA bias circuit 222 and used to generate the plurality of individual bias signals 215 which are input to the individual sub-amplifiers.

In one embodiment, both the splitter and combiner transformers are fabricated in CMOS and integrated on the same die with other analog and digital circuitry. In alternative embodiments, the transformers are fabricated using other technologies such as GaAs, GaN, etc. The transformers comprise air cores and may take on any suitable geometrical shape and configuration. Several examples of integrated multi-tap transformers are described in more detail infra.

In one embodiment, one or more of the configurable sub-power amplifiers, operating in parallel and making up the power amplifier, are identical with each sub-amplifier comprised of separate high and low amplifiers. In alternative embodiment, the sub-amplifiers are not necessarily identical, with each being different to suit desired operating profile points. A high amplifier operates at relatively large backoff (e.g., 12 dB) and is adapted to handle the high peak input amplitudes seen roughly 5% of the time. In one embodiment, the high amplifier is implemented as a class C nonlinear amplifier having appropriate biasing to amplify the peak signals with high efficiency. A low amplifier operates at lower backoff (e.g., 6 dB) and is adapted to handle the lower average input amplitudes seen roughly 95% of the time. In one embodiment, the low amplifier is implemented as a class AB linear amplifier having appropriate biasing to amplify the average signals with high linearity. Note that in an alternative embodiment, each sub-amplifier may comprise more than two amplifiers and/or be implemented using amplifiers other than class AB and C depending on the particular application.

Note that the use of separate high and low amplifiers in each sub-amplifier helps enables the power amplifier and FEM circuit to comply with stringent linearity and spectral efficiency requirements of modern wireless standards, such as 802.11 Wi-Fi (802.11ac in particular), LTE, 3G, 4G, etc., whose signals exhibit high peak to average ratios while providing relatively high efficiency resulting in minimized battery consumption.

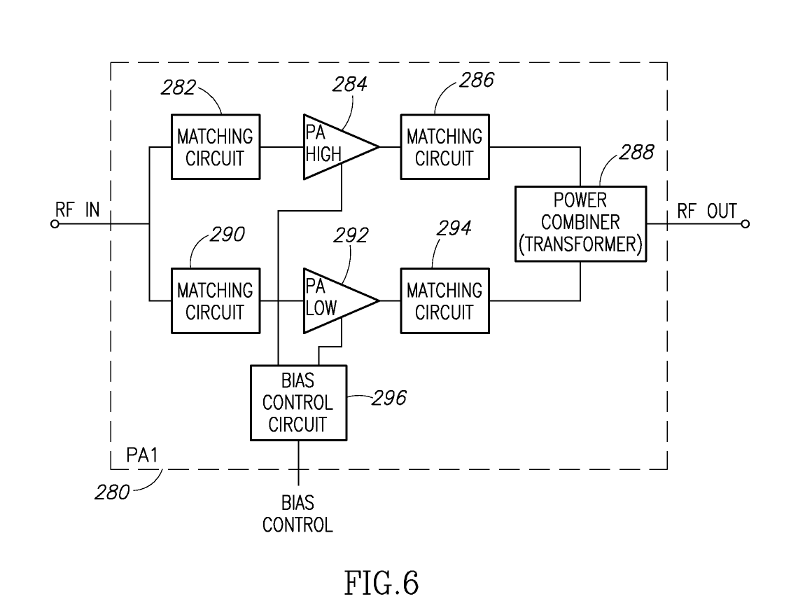

A block diagram illustrating a fourth example TX path portion of the FEM circuit incorporating a distributed power amplifier is shown in FIG. 6. The circuit, generally referenced 280, represents one of the configurable sub-amplifiers of the power amplifier circuit 166, 198, 216 (of FIGS. 3, 4, 5, respectively). In one embodiment, four identical sub-amplifiers are used to generate the total desired power gain. Although in alternative embodiments, they may not be identical and the number of sub-amplifiers is not limited to four but may be any number greater than or equal to one. In this example embodiment, the circuit 280 comprises a high circuit path and a low circuit path. The high path comprises matching circuits 282, 286 and high power amplifier 284. The low path comprises matching circuits 290, 294 and power amplifier 292. Power combiner (e.g., multi-tap transformer) 288 combines the outputs of the high and low amplifiers to generate the RF output for one of the sub-amplifiers. Bias control circuit 296, constructed in accordance with the present invention, functions to control the plurality of bias points of the high and low sub-amplifiers according to a bias control input. In the case of high and low circuit paths, the multi-tap combiner transformer comprises taps for high and low sub-amplifier outputs for each of the sub-amplifiers (four in this example embodiment) making up the power amplifier.

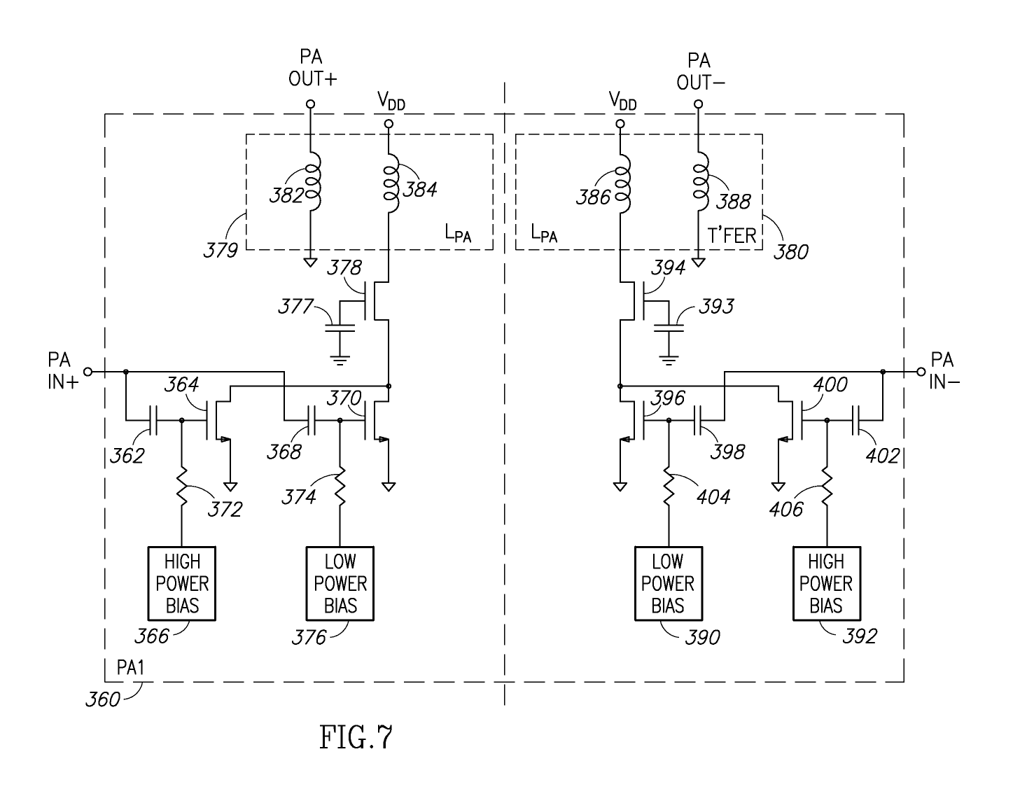

A schematic diagram illustrating a first example differential PA circuit is shown in FIG. 7. The sub-amplifier circuit, generally referenced 360, functions to amplify a differential RF input signal applied to the PA IN+ and PA IN− terminals. The circuit comprises a transistor current modulation topology to amplifier the RF input signal. The outputs of one or more instances of the configurable sub-amplifier, described in detail supra, are combined to generate the RF output signal having the desired total gain. The plus side of the sub-amplifier comprises capacitors 362, 368, 377, resistors 372, 374, transistors 364, 370, 378, low power bias circuit 376, high power bias circuit 366, and transformer 379 having a power amplifier primary winding 384 (L_{PA}) and secondary winding 382. Similarly, the minus side of the sub-amplifier comprises capacitors 402, 398, 393, resistors 404, 406, transistors 400, 396, 394, low power bias circuit 390, high power bias circuit 392, and transformer 380 having a power amplifier primary winding 386 (L_{PA}) and secondary winding 388.

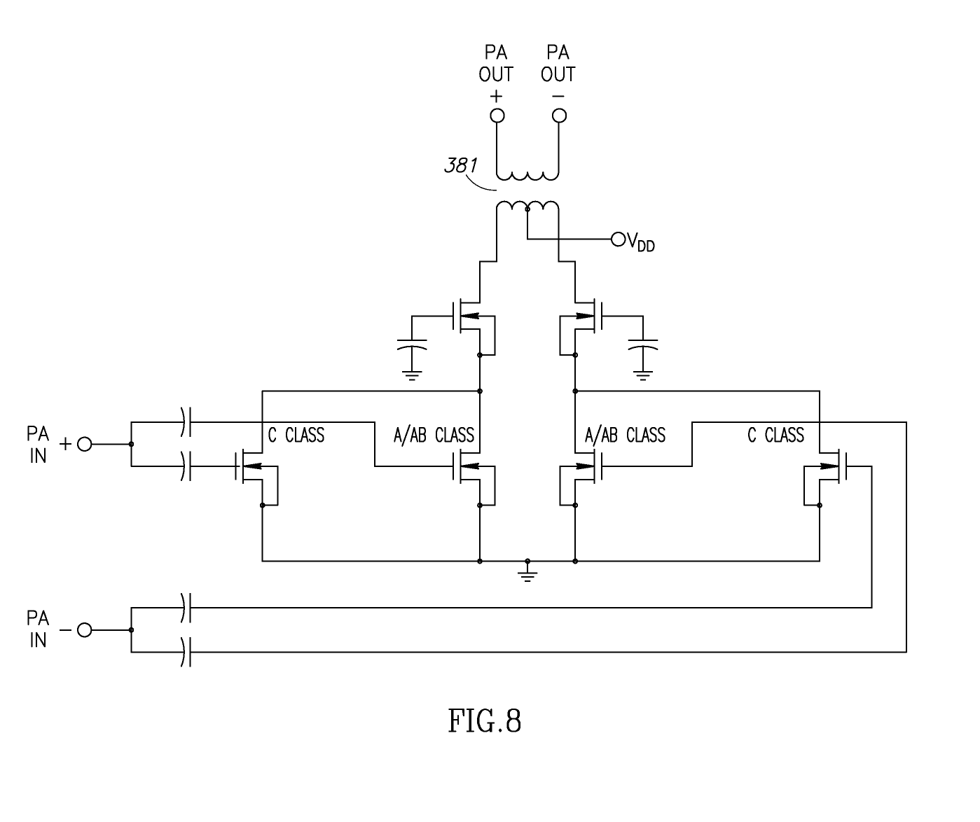

In one example embodiment, the bias control profile may operate to bias the low power transistors of both plus and minus circuits for and to operate as linear class A/AB amplifiers for average amplitude inputs while the high power transistors of both plus and minus circuits are biased for and operate as high efficiency class C amplifiers for peak amplitude inputs. The power generated by the high and low portion of the sub-amplifier is combined in the transistor circuit (370, 364 and 396, 400) via current combining FIG. 8 illustrates the sub-amplifier output connections to the integrated transformer 381 in more detail.

A schematic diagram illustrating a second example differential PA circuit is shown in

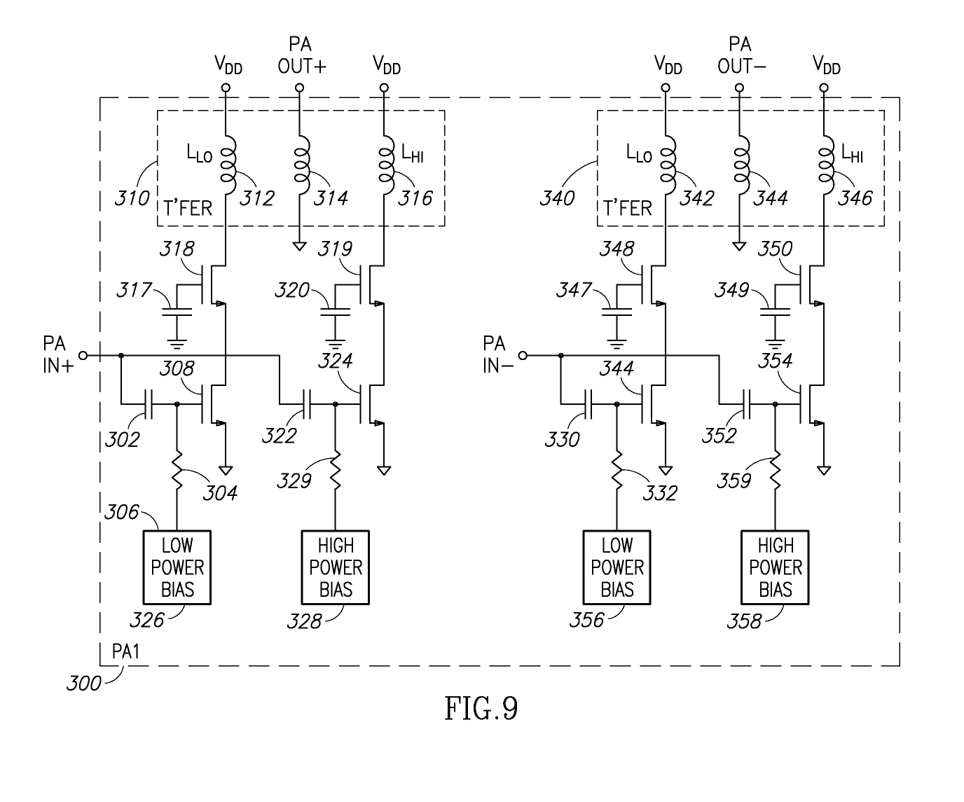

FIG. 9. The configurable sub-amplifier circuit, generally referenced 300 and described in detail supra, functions to amplify a differential RF input signal applied to the PA IN+ and PA IN− terminals. The outputs of one or more instances of the sub-amplifier are combined to generate the RF output signal having the desired total gain.

The plus side of the sub-amplifier comprises capacitors 302, 317, 319, 322, resistors 304, 329, transistors 318, 320 and 308, 324, low power bias circuit 326 and high power bias circuit 328, and transformer 310 having low primary winding 312 (L_{LO}), high primary winding 316 (L_{HI}) and secondary winding 314 (PA OUT+). Similarly, the minus side of the sub-amplifier comprises capacitors 330, 347, 349, 352, resistors 332, 359, transistors 348, 350 and 334, 354, low power bias circuit 356 and high power bias circuit 358, and transformer 340 having low primary winding 342 (L_{LO}), high primary winding 346 (L_{HI}) and secondary winding 344 (PA OUT−).

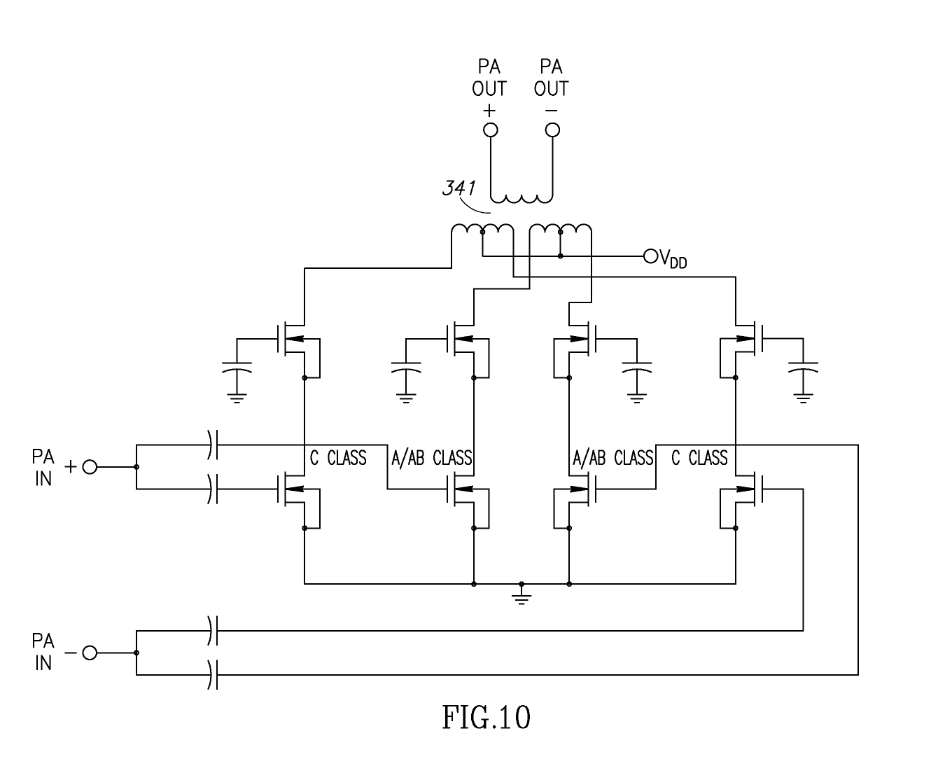

In operation, the low power transistors of both plus and minus circuits are biased for and operate as linear class A/AB amplifiers for average amplitude inputs while the high power transistors of both plus and minus circuits are biased for and operate as high efficiency class C amplifiers for peak amplitude inputs. In this embodiment, the power generated by the high and low portions of the sub-amplifier is combined magnetically in the transformer circuit (312, 316 and 342, 346). FIG. 10 illustrates the sub-amplifier output connections to the integrated transformer 341 in more detail.

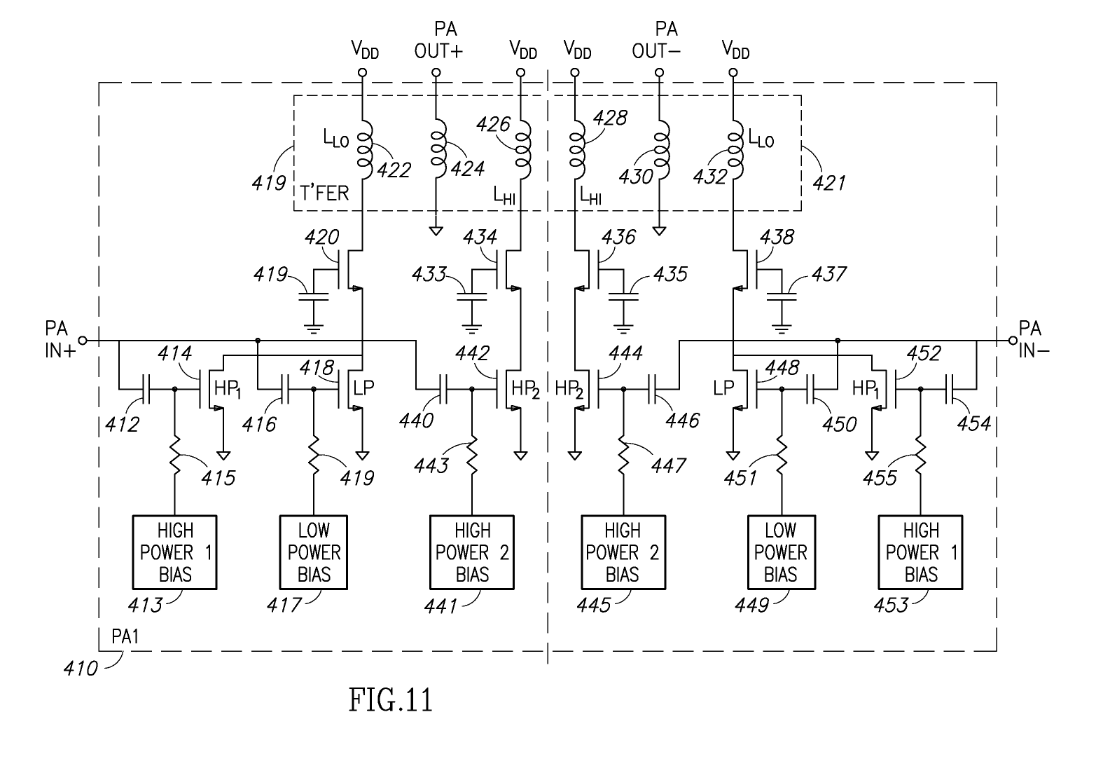

A schematic diagram illustrating a third example differential PA circuit is shown in FIG. 11. This configurable sub-amplifier circuit is similar to the circuit shown in FIG. 9 with low and high power transistor paths. The difference being the addition of a second high power transistor (HP1) in parallel with the low power transistor (LP).

The sub-amplifier circuit, generally referenced 410, functions to amplify a differential input signal applied to the PA IN+ and PA IN− terminals. The outputs of one or more instances of the sub-amplifier are combined to generate the RF output signal having the desired total gain.

The plus side of the sub-amplifier comprises capacitors 412, 416, 440, 419, 433, resistors 415, 419, 443, transistors 418 (LP), 414 (HP1), 442 (HP2) and 420, 434, low power bias circuit 417, high power 1 bias circuit 413 and high power 2 bias circuit 441, and transformer 419 having low primary winding 422 (L_{LO}), high primary winding 426 (L_{HI}) and secondary winding 424 (PA OUT+). Similarly, the minus side of the sub-amplifier comprises capacitors 446, 450, 454, 435, 437, resistors 447, 451, 455, transistors 448 (LP), 452 (HP1), 444 (HP2) and 436, 438, low power bias circuit 449, high power 1 bias circuit 453 and high power 2 bias circuit 445, and transformer 421 having low primary winding 432 (L_{LO}), high primary winding 428 (L_{HI}) and secondary winding 430 (PA OUT−).

In operation, the low power transistors of both plus and minus circuits are biased for and operate as linear class A/AB amplifiers for average amplitude inputs while the high power 1 and high power 2 transistors of both plus and minus circuits are biased for and operate as high efficiency class C amplifiers for peak amplitude inputs. In this embodiment, the power generated by the high and low portions of the sub-amplifier is combined magnetically in the transformer circuit (422, 426 and 428, 432).

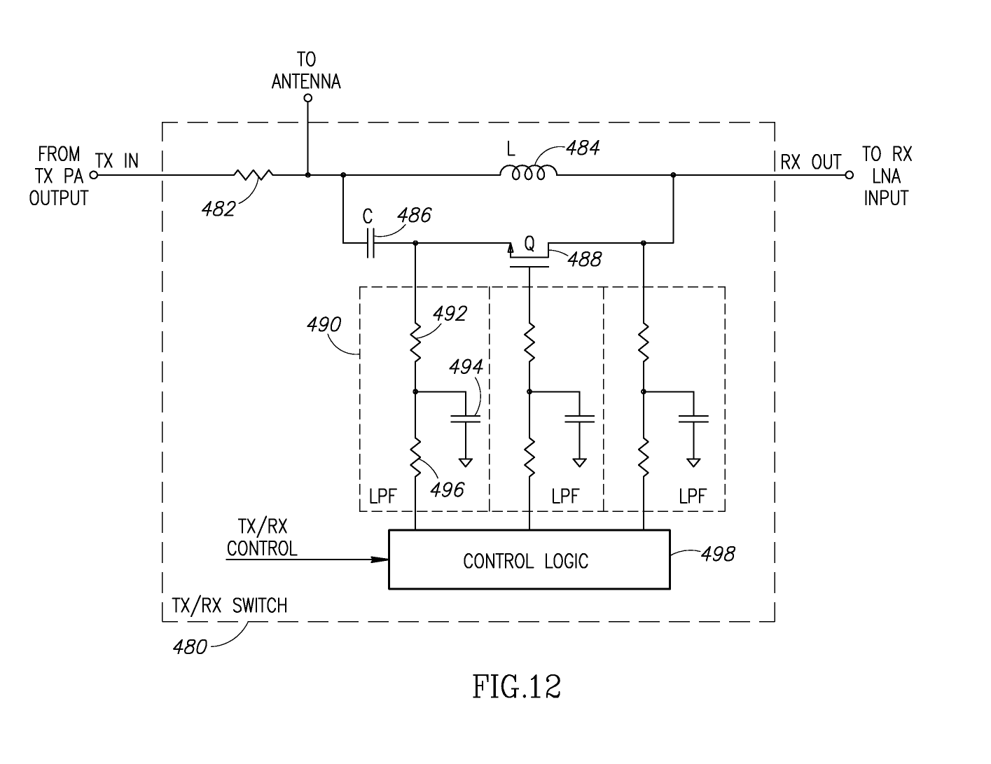

A schematic diagram illustrating a first example TX/RX switch is shown in FIG. 12. The switch circuit, generally referenced 480, comprises a TX input port coupled to resistor R 482, inductor L 484 coupled to an RX output port, an antenna port, capacitor C 486, transistor Q 488, low pass filters 490 and control logic circuit 498. Each low pass filter comprises resistors 492, 496 and capacitor 494 coupled to ground and connected in a ‘T’ configuration.

In operation, the TX/RX switch is placed in receive mode by turning transistor Q off. In this mode, the signal path is from the antenna through inductor L to the LNA circuit. In one embodiment, the inductor may comprise an inductance of 1.4 nH. Alternatively, the inductor may be implemented as a bond wire having a suitable thickness (e.g., 0.7 mil) and length connected to a dummy pad.

To place the TX/RX switch into the transmit mode, transistor Q is turned on. In this mode, the combination of capacitor C and inductor L form a parallel resonant circuit and thus present a high impedance to the output of the transmitter while exhibiting a low insertion loss of less than 0.5 dB. The power from the transmitter is transferred to the antenna via resister R.

In one embodiment, the switch is implemented using standard CMOS technology. In another embodiment, a PIN diode is used to implement the switch along with the appropriate peripheral components that are used for biasing and matching networks. In an alternative embodiment, gallium arsenide (GaAs) based switches are used to implement the RF switch. GaAs based switches provide good linearity and isolation with low on resistance and off capacitance. Disadvantages of GaAs, however, include (1) the requirement of negative gate voltage to turn off due to their N-channel depletion mode configuration; (2) driving GaAs switches typically requires additional interface components; and (3) the difficulty of integrating other functions such as logic control and memory on the same chip.

In one embodiment, the RF switch is implemented entirely in CMOS and exhibits, high power, low current and high isolation while enabling integration with logic control circuitry and other digital circuitry based functions. Such an RF switch may be incorporated into a wireless device such as a mobile phone, cordless phone, etc. described in more detail infra.

Consider a wireless device such as a cordless phone including a base and one or more handsets. The handset usually comprises a single antenna with the recent trend of manufacturers implementing antenna diversity in the handset. Due to relatively small physical dimensions of the hand-set, regular space diversity is not practical. Thus, cordless phone manufacturers implement polarization diversity in hand-sets where one of the antennas is vertically polarized while a second antenna is horizontally polarized. This can improve the performance of the link up to 6 dB, on top of approximately 10 dB statistical improvement of diversity antenna in the base. The integrated CMOS DPDT switch of the present invention has additional advantages in the case of antenna diversity in hand-sets (HS) including requiring less PCB area which is critical in HS design; easy integration; and low BOM. The base station may comprise one or two antennas placed at a spatial angle to each other. At each point in time, space diversity is achieved, e.g., an antenna for which the direct wave and the reflected wave create constructive interference rather than destructive interference.

The logic control circuit 498 functions to generate the biasing voltages for the drain, source and gate terminals of transistor Q. The biasing signals are applied through the low pass filter networks 490 to the drain, source and gate of the transistor Q. The function of the LPF circuits 490 is to suppress the RF leakage from the drain, source and gate to the logic control circuit 498. Note that other RC type filter networks can be used without departing from the scope of the invention as is known in the art. Note also that the use of the RC filter networks avoids the needs for RF chokes which is desirable when implementing the switch in CMOS circuitry. Alternatively, RF chokes may be used either external to the chip or integrated therein.

In one embodiment, for the switch to operate at relatively high TX power levels (e.g., >25 dBm) and high VSWR, a deep N-well CMOS process is used to construct the N-channel FET 488.

In one embodiment, to turn the transistor Q on, a relatively high voltage (e.g., 3.6V) is applied to the gate while the drain and source terminals are connected to ground. Thus, V_{GS} is 3.6V forward biasing the transistor. To turn the transistor Q off, a high voltage (e.g., 3.6V) is applied to the drain and source while the gate is connected to ground. Thus, V_{GS} is −3.6V reverse biasing the transistor. It is noted that reverse biasing the transistor to be turned off rather than connecting the gate, drain and source to ground (or controlling the gate terminal only and keeping drain and source biasing constant) enables the RF switch to achieve significantly higher isolation on the order of approximately 17 dB.

The low pass filter networks 490 on the source, drain and gate terminals also function to provide termination so that the antenna has constant impedance relative to ground. The primary purpose of the LPF is to suppress the RF leakage from the drain, gate and source to the logic control circuit, thus preventing RF signal loss in the logic control circuit. This is achieved by configuring the switch circuit such that the impedance of the NMOS transistor is determined only by the physical parameters of the NMOS transistor itself (e.g., R_{DS-ON}, C_{DS-OFF}, C_{G}, C_{D}, C_{S}) and is independent of the logic control circuit.

It is appreciated that the logic control circuit is exemplary only and other components can be used for enabling the transistor Q to function such that each is turned on and off with the correct timing and synchronization in accordance with the particular application. The transistor Q and all related components can be placed on-chip, thus reducing cost.

It will also be appreciated that the RC network for the low pass filters and other components associated with the transistor Q are an example and that other circuits that perform similar functions may be used as is known in the electrical arts.

The logic control circuit controls the gate, drain and source of the transistor Q. The configuration and use of CMOS technology provide for low current consumption on the order of microamperes, as well as high isolation and flexibility as compared to prior art switches.

Note that the disclosed RF switch can also be used in environments in which one or more antennas are available, such as in handsets with or without antenna diversity, and with and without MIMO capability. The RF switch is not limited for use to any type of device and can be used for any environment in which multiple switches are required, such as wireless local area network access points (WLAN AP), cellular phones, cordless phones, communication systems, radar systems or the like.

In an alternative embodiment, the RF switch configuration can be expanded to include additional transistors and control circuits for switching between additional ports, e.g., additional antenna, TX and RX ports. A switch matrix can be used, such as an N×M matrix of elements, wherein each element is implemented as a single NMOS transistor, an L series shunt combination, or a T or PI combination. Any of these combinations can be implemented as a complementary switch, comprising NMOS and PMOS. It will be appreciated that various modifications and variations can be designed. For example, different peripheral components and control circuits can be used.

As described supra, the SPDT switch comprises three external terminals (i.e. pins or ports): Antenna, TX and RX. In one embodiment, for each of the terminals (pins) there are one or more parallel and/or series bond wires that connect the external pins to the internal on die SPDT terminals (i.e. bonding pads). In one embodiment, the bond wires measure a nominal 0.7 mil in diameter and made of copper or gold. The bond wires function not only connect the internal circuitry on the semiconductor die to the external pins of the device package but also function tune out or offset the capacitance of the transistors. The one or more bond wires per pin exhibit a relatively high Q factor which contributes to a lower insertion loss for the connection. The particular die position and the number of parallel bond wires used is adapted so as to tune out the NMOS switch input capacitance, thus simplifying the external matching network and achieving a lower insertion loss for the switch. This is described in more detail infra

In particular, the one or more bond wires coupling the external TX pin to the semiconductor die is operative to tune out the capacitance of the drain of NMOS transistor Q. The one or more bond wires coupling the external antenna pin to the semiconductor die is operative to tune out the capacitance of the source of NMOS transistor Q. The one or more bond wires coupling the external RX pin to the semiconductor die is operative to tune out the capacitance of the drains of NMOS transistor Q. The combination of the bonding wire and external PCB based shunt capacitor form a matching network disposed between the TX, RX and antenna and the switching transistor Q.

At each junction the circuit sees either twice the drain capacitance or twice the source capacitance. Due to the relatively large area of the NMOS devices (e.g., on the order of 1 mm wide), this capacitance is on the order of 0.5 to 1.5 pF. In order to tune out this capacitance as seen at the input ports, the inductance presented by the bond wire (one or more in parallel and/or series) in combination with the PCB copper traces is adapted to resonate and form a tuned circuit in the range of desired frequencies. The off-chip external parallel shunt capacitor on the PCB functions, in combination with the inductance of the bond wires to present a matching 50 Ohms impedance to the TX, RX and antenna ports. Note that the bond wires are typically part of a package (e.g., quad, flat, no leads or QFN) having a diameter of 0.7 to 1 mils and constructed from gold, copper or aluminum.

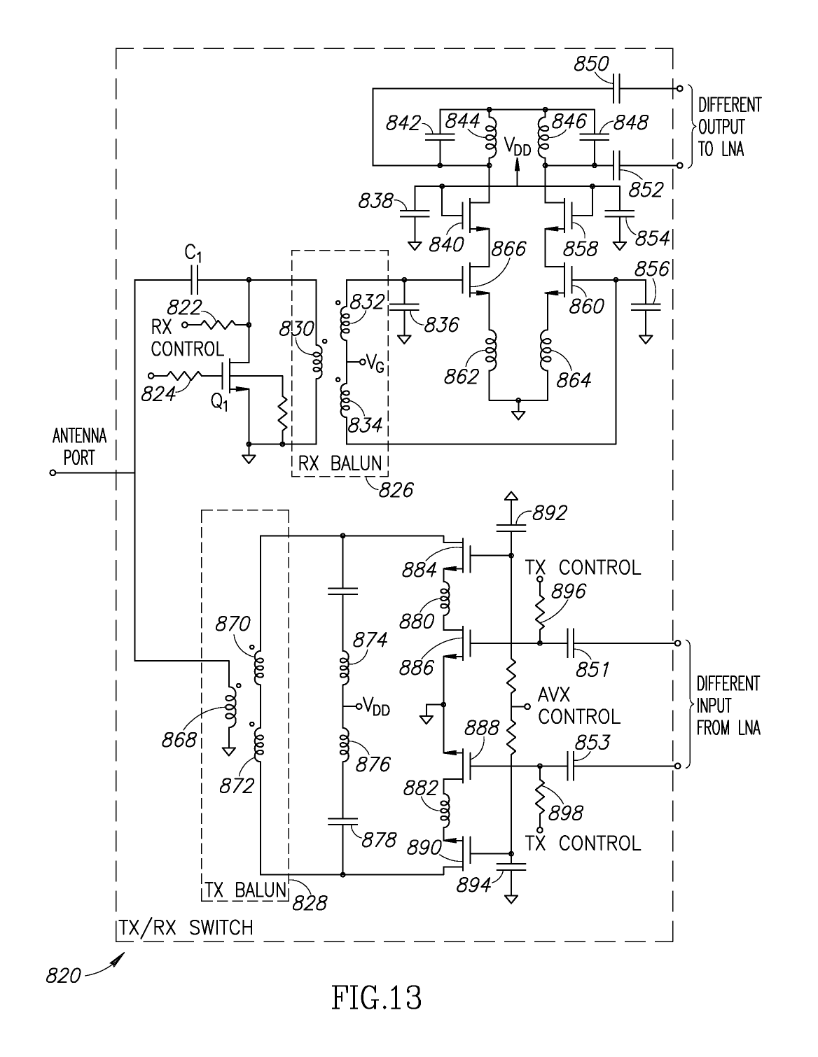

A schematic diagram illustrating a second example TX/RX switch is shown in FIG. 13. The switch includes integrated TX and RX baluns and a common TX/RX single ended antenna port. A combination of a high pass filter and a shunt NMOS switch Q1 enable relatively high TX/RX isolation and low chip area. The switch, generally referenced 820, comprises transmit portion for coupling a differential input from a power amplifier to an antenna and a receive portion for coupling a signal received on the antenna to a differential output to a low noise amplifier (LNA) circuit. The transmit portion comprises capacitors 851, 853, 873, 878, 892, 894, inductors 880, 882, 874, 876, TX balun 828 including transformer windings 868, 870, 872, transistors 884, 886, 888, 890 and resistors 891, 893, 896, 898. The receive portion comprises capacitors C1, 836, 838, 842, 848, 854, 856, 850, 852, inductors 862, 864, 844, 846, RX balun 826 including transformer windings 830, 832, 834, transistors Q1, 866, 860, 840, 858 and resistors 822, 824, 823.

Operation of the switch includes applying appropriate control signals to the RX control input and the TX control inputs. To place the TX/RX switch in receive mode, the RX control is configured to turn Q1 off and the TX control is configured to turn transistors 886, 888 off. Turning Q1 off permits the receive signal from the antenna to pass through the RX balun 826 to differential transistor pair 866, 860. The differential signal generated is output to the LNA circuit (134 in FIG. 2 for example).

To place the TX/RX switch in transmit mode, the RX control is configured to turn Q1 on and the TX control is configured to turn transistors 886, 888 on. Turning Q1 on blocks the transmit signal from entering the receive circuit path. The differential signal input from the power amplifier is input to transistors 886, 888 and subsequently applied to the TX balun 828 whose output is input to the antenna port.

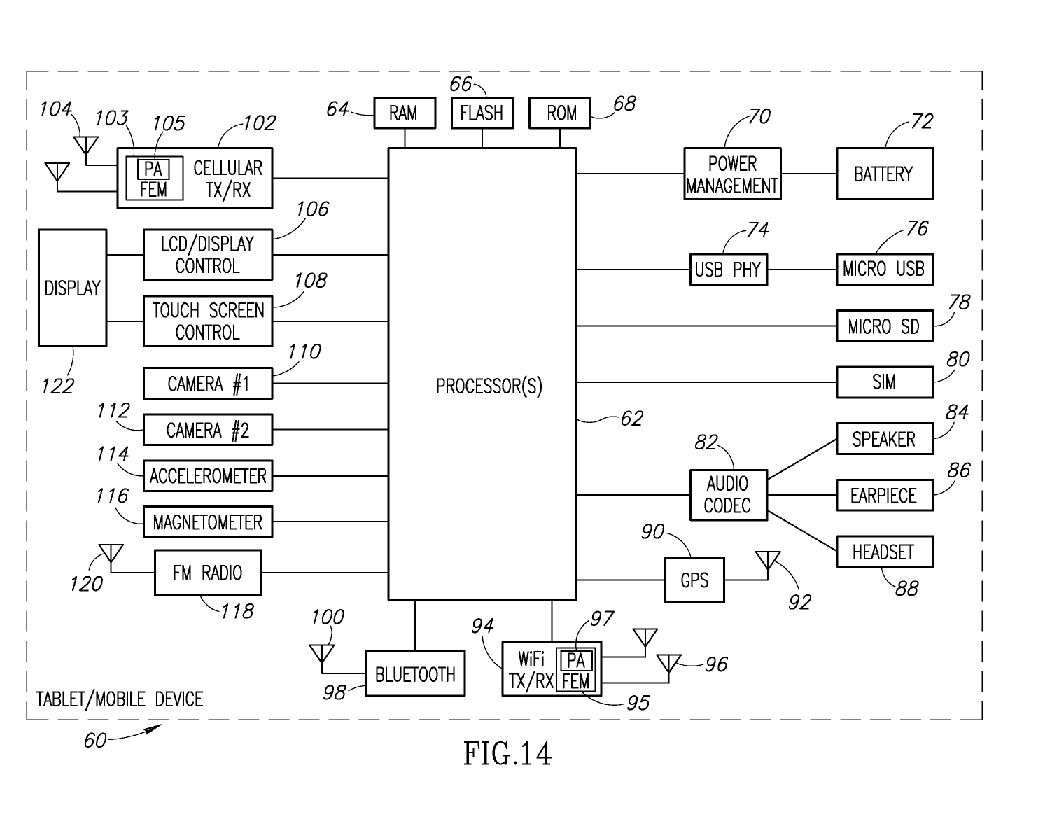

A high level block diagram illustrating an example wireless device incorporating a FEM circuit with distributed power amplifier of the present invention is shown in FIG. 14. The tablet/mobile device is preferably a two-way communication device having voice and/or data communication capabilities. In addition, the device optionally has the capability to communicate with other computer systems via the Internet. Note that the device may comprise any suitable wired or wireless device such as multimedia player, mobile communication device, cellular phone, cordless phone, smartphone, PDA, PNA, Bluetooth device, tablet computing device such as the iPad, Galaxy, etc. For illustration purposes only, the device is shown as a mobile device, such as a cellular based telephone, cordless phone, smartphone or superphone. Note that this example is not intended to limit the scope of the mechanism as the invention can be implemented in a wide variety of communication devices. It is further appreciated the mobile device shown is intentionally simplified to illustrate only certain components, as the mobile device may comprise other components and subsystems beyond those shown.

The mobile device, generally referenced 60, comprises one or more processors 62 which may comprise a baseband processor, CPU, microprocessor, DSP, etc., optionally having both analog and digital portions. The mobile device may comprise a plurality of radios 102 (e.g., cellular, cordless phone, etc.), FEM circuit 103 with configurable power amplifier 105 constructed in accordance with the present invention and associated one or more antennae 104. Radios for the wireless link and any number of other wireless standards and Radio Access Technologies (RATs) may be included. Examples include, but are not limited to, Digital Enhanced Cordless Telecommunications (DECT), Code Division Multiple Access (CDMA), Personal Communication Services (PCS), Global System for Mobile Communication (GSM)/GPRS/EDGE 3G; WCDMA; WiMAX for providing WiMAX wireless connectivity when within the range of a WiMAX wireless network; Bluetooth for providing Bluetooth wireless connectivity when within the range of a Bluetooth wireless network; 802.11 WLAN for providing wireless connectivity when in a hot spot or within the range of an ad hoc, infrastructure or mesh based wireless LAN (WLAN) network; near field communications; UWB; GPS receiver for receiving GPS radio signals transmitted from one or more orbiting GPS satellites, FM transceiver provides the user the ability to listen to FM broadcasts as well as the ability to transmit audio over an unused FM station at low power, such as for playback over a car or home stereo system having an FM receiver, digital broadcast television, etc.

The mobile device may also comprise internal volatile storage 64 (e.g., RAM) and persistent storage 68 (e.g., ROM) and flash memory 66. Persistent storage 68 also stores applications executable by processor(s) 62 including the related data files used by those applications to allow device 60 to perform its intended functions. Several optional user-interface devices include trackball/thumbwheel which may comprise a depressible thumbwheel/trackball that is used for navigation, selection of menu choices and confirmation of action, keypad/keyboard such as arranged in QWERTY fashion for entering alphanumeric data and a numeric keypad for entering dialing digits and for other controls and inputs (the keyboard may also contain symbol, function and command keys such as a phone send/end key, a menu key and an escape key), headset 88, earpiece 86 and/or speaker 84, microphone(s) and associated audio codec or other multimedia codecs, vibrator for alerting a user, one or more cameras and related circuitry 110, 112, display(s) 122 and associated display controller 106 and touchscreen control 108. Serial ports include a micro USB port 76 and related USB PHY 74 and micro SD port 78. Other interface connections may include SPI, SDIO, PCI, USD, etc. for providing a serial link to a user's PC or other device. SIM/RUIM card 80 provides the interface to a user's SIM or RUIM card for storing user data such as address book entries, user identification, etc.

Portable power is provided by the battery 72 coupled to power management circuitry 70. External power is provided via USB power or an AC/DC adapter connected to the power management circuitry which is operative to manage the charging and discharging of the battery. In addition to a battery and AC/DC external power source, additional optional power sources each with its own power limitations, include: a speaker phone, DC/DC power source, and any bus powered power source (e.g., USB device in bus powered mode).

Operating system software executed by the processor 62 is preferably stored in persistent storage (i.e. ROM 68), or flash memory 66, but may be stored in other types of memory devices. In addition, system software, specific device applications, or parts thereof, may be temporarily loaded into volatile storage 64, such as random access memory (RAM). Communications signals received by the mobile device may also be stored in the RAM.

The processor 62, in addition to its operating system functions, enables execution of software applications on the device 60. A predetermined set of applications that control basic device operations, such as data and voice communications, may be installed during manufacture. Additional applications (or apps) may be downloaded from the Internet and installed in memory for execution on the processor. Alternatively, software may be downloaded via any other suitable protocol, such as SDIO, USB, network server, etc.

Other components of the mobile device include an accelerometer 114 for detecting motion and orientation of the device, magnetometer 116 for detecting the earth's magnetic field, FM radio 118 and antenna 120, Bluetooth radio 98 and antenna 100, 802.11 (including standards ‘a’, ‘b’, ‘g’, ‘n’, ‘ac’ for example) based Wi-Fi radio 94 (including FEM circuit 95 with configurable power amplifier 97 constructed in accordance with the present invention and one or more antennae 96) and GPS 90 and antenna 92.

In accordance with the invention, the mobile device 60 is adapted to implement the electronic catalog system as hardware, software or as a combination of hardware and software. In one embodiment, implemented as a software task, the program code operative to implement the electronic catalog system is executed as one or more tasks running on processor 62 and either (1) stored in one or more memories 64, 66, 68 or (2) stored in local memory within the processor 62 itself.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. As numerous modifications and changes will readily occur to those skilled in the art, it is intended that the invention not be limited to the limited number of embodiments described herein. Accordingly, it will be appreciated that all suitable variations, modifications and equivalents may be resorted to, falling within the spirit and scope of the present invention. The embodiments were chosen and described in order to best explain the principles of the invention and the practical application, and to enable others of ordinary skill in the art to understand the invention for various embodiments with various modifications as are suited to the particular use contemplated.

What is claimed is:

1. A configurable radio frequency (RF) power amplifier, comprising:
an input node for receiving an RF input signal;
an output node for driving a load;
a plurality of individually configurable sub-amplifiers configured in parallel and operatively coupled to said input node, each sub-amplifier operative to amplify its respective RF input signal to generate a sub-amplifier output signal therefrom;
a control circuit operative to set the operating parameters of each individual sub-amplifier in accordance with a desired operating point;
wherein the operating parameters of each sub-amplifier are independently and individually controlled, thereby providing the ability to configure the frequency response and linearity of said configurable power amplifier; and
wherein the outputs of each sub-amplifier are combined to generate said output node.

2. The power amplifier according to claim 1, wherein each said sub-amplifier is operative to have multiple orders of freedom via multiple biasing points such that gain and saturation point, frequency response, linearity level and EVM of said configurable power amplifier can be set to a desired level.

3. The power amplifier according to claim 1, wherein said control circuit comprises one or more internal biasing circuits operative to generate bias signals for said plurality of sub-amplifiers.

4. The power amplifier according to claim 1, wherein said control circuit is operative to receive one or more external bias settings used to generate bias signals for said plurality of sub-amplifiers.

5. The power amplifier according to claim 1, wherein the operating parameters for each individual sub-amplifier are derived from an internal predefined bias setting memory store.

6. The power amplifier according to claim 1, wherein the operating parameters for each individual sub-amplifier are derived from one or more externally received bias setting signals.

7. The power amplifier according to claim 1, wherein said control circuit comprises an active bias circuit operative to generate individual bias signals for each sub-amplifier.

8. The power amplifier according to claim 7, wherein the active bias circuit generates said bias signals in accordance with an internal predefined bias setting memory store.

9. The power amplifier according to claim 8, wherein said internal predefined bias setting memory store comprises a look up table (LUT).

10. The power amplifier according to claim 7, wherein the active bias circuit generates said bias signals in accordance with one or more external bias setting signals.

11. The power amplifier according to claim 1, wherein said power amplifier is fabricated using a semiconductor technology selected from the group consisting of complementary metal oxide semiconductor (CMOS), Gallium Arsenide (GaAs), Silicon Germanium (SiGe), Indium Gallium Phosphide (InGaP) and Gallium Nitride (GaN).

12. The power amplifier according to claim 1, wherein said power amplifier is adapted to transmit signals conforming to a wireless standard selected from the group consisting of 802.11 WLAN, LTE, WiMAX, HDTV, 3G cellular, 4G cellular and DECT.

13. A configurable radio frequency (RF) power amplifier, comprising:
an input node for receiving an RF input signal;
an output node for driving a load;
a driver/splitter circuit operatively coupled to said input node and adapted to split said input RF signal into a plurality of RF signals;
a plurality of individually configurable sub-amplifiers operatively coupled to said driver/splitter circuit, wherein each sub-amplifier is adapted to receive one of said RF signals, each sub-amplifier operative to amplify its respective RF input signal to generate a sub-amplifier output signal therefrom, each sub-amplifier biased independently in accordance with respective one or more configurable control points;
wherein the operating parameters of each sub-amplifier are independently and individually controlled via said one or more configurable control points, thereby providing the ability to configure the frequency response and linearity of said power amplifier;
a control circuit operative to generate and configure said one or more configurable control points for each individual sub-amplifier in accordance with a desired operating point for said power amplifier; and
a power combiner operatively coupled to said plurality of sub-amplifiers and adapted to combine the power generated by each sub-amplifier to generate said output node thereby.

14. The power amplifier according to claim 13, wherein each said sub-amplifier is operative to have multiple orders of freedom via multiple biasing points such that gain and saturation point, frequency response, linearity level and EVM of said configurable power amplifier can be set to a desired level.

15. The power amplifier according to claim 13, wherein said control circuit comprises one or more internal biasing circuits operative to generate bias signals for said plurality of sub-amplifiers.

16. The power amplifier according to claim 13, wherein said control circuit is operative to receive one or more external bias settings used to generate bias signals for said plurality of sub-amplifiers.

17. The power amplifier according to claim 13, wherein the operating parameters for each individual sub-amplifier are derived from an internal predefined bias setting memory store.

18. The power amplifier according to claim 13, wherein the operating parameters for each individual sub-amplifier are derived from one or more externally received bias setting signals.

19. The power amplifier according to claim 13, wherein said control circuit comprises an active bias circuit operative to generate individual bias signals for each sub-amplifier.

20. The power amplifier according to claim 19, wherein the active bias circuit generates said bias signals in accordance with an internal predefined bias setting memory store.

21. The power amplifier according to claim 20, wherein said internal predefined bias setting memory store comprises a look up table (LUT).

22. The power amplifier according to claim 19, wherein the active bias circuit generates said bias signals in accordance with one or more external bias setting signals.

23. The power amplifier according to claim 13, wherein said one or more configurable control points comprises a bias control signal.

24. The power amplifier according to claim 13, wherein the linearity exhibited by said power amplifier is sufficient for non-simultaneous use with 3G and 4G signals in adjacent frequencies with a targeted required error vector magnitude (EVM).

25. The power amplifier according to claim 13, wherein said power amplifier has sufficient configurable points such that desired error vector magnitude (EVM) targets are met.

26. The power amplifier according to claim 13, wherein said power amplifier is fabricated using a semiconductor technology selected from the group consisting of complementary metal oxide semiconductor (CMOS), Gallium Arsenide (GaAs), Silicon Germanium (SiGe), Indium Gallium Phosphide (InGaP) and Gallium Nitride (GaN).

27. The power amplifier according to claim 13, wherein said power amplifier is adapted to transmit signals conforming to a wireless standard selected from the group consisting of 802.11 WLAN, LTE, WiMAX, HDTV, 3G cellular, 4G cellular and DECT.

28. A configurable radio frequency (RF) power amplifier for use in a front end module (FEM) integrated circuit, comprising:
an input node for receiving an RF input signal;
an output node for driving a load;
a driver/splitter circuit operatively coupled to said input node and adapted to split said input RF signal into a plurality of RF signals;
a plurality of individually configurable sub-amplifiers operatively coupled to said driver/splitter circuit, wherein each sub-amplifier is adapted to receive one of said RF signals, each sub-amplifier operative to amplify its respective RF input signal to generate a sub-amplifier output signal therefrom, each sub-amplifier biased independently in accordance with a bias signal;
a bias signal generation circuit operative to generate said bias signals for each individual sub-amplifier in accordance with an external bias setting representing a desired operating point for said power amplifier;
wherein the operating parameters of each sub-amplifier are independently and individually controlled via a respective bias signal generated in accordance with said external bias setting, thereby providing the ability to configure the frequency response and linearity of said power amplifier as a whole; and
a power combiner operatively coupled to said plurality of sub-amplifiers and adapted to combine the power generated by each sub-amplifier to generate said output node thereby. Same comments as above

29. The power amplifier according to claim 28, wherein said power amplifier is fabricated using a semiconductor technology selected from the group consisting of complementary metal oxide semiconductor (CMOS), Gallium Arsenide (GaAs), Silicon Germanium (SiGe), Indium Gallium Phosphide (InGaP) and Gallium Nitride (GaN).

30. The power amplifier according to claim 28, wherein said power amplifier is adapted to transmit signals conforming to a wireless standard selected from the group consisting of 802.11 WLAN, LTE, WiMAX, HDTV, 3G cellular, 4G cellular and DECT.

31. A configurable radio frequency (RF) power amplifier for use in a front end module (FEM) integrated circuit, comprising:
an input node for receiving an RF input signal;
an output node for driving a load;
a driver/splitter circuit operatively coupled to said input node and adapted to split said input RF signal into a plurality of RF signals;
a plurality of individually configurable sub-amplifiers operatively coupled to said driver/splitter circuit, wherein each sub-amplifier is adapted to receive one of said RF signals, each sub-amplifier operative to amplify its respective RF input signal to generate a sub-amplifier output signal therefrom, each sub-amplifier biased independently in accordance with a bias signal;
a bias signal generation circuit operative to generate said bias signals for each individual sub-amplifier in accordance with a bias control signal representing a desired operating point for the entire power amplifier;
a bias control circuit operative to generate said bias control signal in accordance with a desired operating setting stored in a bias setting table;
said operating setting table operative to store a plurality of settings for said bias signal generation circuit, each setting entry in said table representing a different desired operating point for said power amplifier;
wherein the operating parameters of each sub-amplifier are independently and individually controlled via a respective bias signal, thereby providing the ability to configure the frequency response and linearity of said power amplifier as a whole; and
a power combiner operatively coupled to said plurality of sub-amplifiers and adapted to combine the power generated by each sub-amplifier to generate said output node thereby.

32. The power amplifier according to claim 31, wherein said power amplifier is fabricated using a semiconductor technology selected from the group consisting of complementary metal oxide semiconductor (CMOS), Gallium Arsenide (GaAs), Silicon Germanium (SiGe), Indium Gallium Phosphide (InGaP) and Gallium Nitride (GaN).

33. The power amplifier according to claim 31, wherein said power amplifier is adapted to transmit signals conforming to a wireless standard selected from the group consisting of 802.11 WLAN, LTE, WiMAX, HDTV, 3G cellular, 4G cellular and DECT.

34. A multimode, multiband configurable radio frequency (RF) power amplifier, comprising:
an input node for receiving an RF input signal;
an output node for driving a load;
a plurality of individually configurable sub-amplifiers configured in parallel and operatively coupled to said input node, the operating parameters of each sub-amplifier capable of being independently controlled in accordance with a desired operating point, each sub-amplifier operative to amplify its respective RF input signal to generate a sub-amplifier output signal therefrom;
wherein said individually configurable sub-amplifiers enable said power amplifier to transmit in accordance with a first wireless standard in a first frequency band and after a change in one or more operating parameters of one or more sub-amplifiers, transmit in accordance with a second wireless standard in a second frequency band; and
wherein the outputs of each sub-amplifier are combined to generate said output node.
